(19) United States
(12) Patent Application Publication
(10) Pub. No.: US 2018/0074091 A1
(43) Pub. Date: Mar. 15, 2018

(54) PIEZORESISTIVE SENSOR

(71) Applicant: Murata Manufacturing Co., Ltd., Nagaokakyo-shi (JP)

(72) Inventors: Ryunosuke HINO, Nagaokakyo-shi (JP); Hiroshi HAMAMURA, Nagaokakyo-shi (JP)

(21) Appl. No.: 15/691,790

(22) Filed: Aug. 31, 2017

(30) Foreign Application Priority Data
Sep. 13, 2016 (JP) 2016-178379

(51) Int. Cl. G01P 15/12; G01C 19/56; H01L 29/84; H01L 29/167; H01L 29/36

(52) U.S. Cl. CPC G01P 15/123; G01C 19/56; H01L 29/36; H01L 29/167; H01L 29/84

(57) ABSTRACT

A piezoresistive sensor includes a first detection beam including a first piezoresistor and a first base in which the first piezoresistor is embedded. The first base includes a depletion layer that surrounds the first piezoresistor, a first region made of a semiconductor having a polarity different from a polarity of the first piezoresistor, and second regions each made of a semiconductor having a polarity different from the polarity of the first piezoresistor and an impurity concentration higher than an impurity concentration of the first region. Each second region is exposed from a corresponding one of side surfaces of the first detection beam. The depletion layer is surrounded by a region defined by the first region and the second regions. Other detection beams have the same structure.

### CROSS REFERENCE TO RELATED APPLICATIONS

This application claims the benefit of priority to Japanese Patent Application No. 2016-178379 filed on Sep. 13, 2016. The entire contents of this application are hereby incorporated herein by reference.

### BACKGROUND OF THE INVENTION

### 1. Field of the Invention

The present invention relates to a piezoresistive sensor used to detect inertial force, such as angular acceleration, angular speed, and acceleration.

### 2. Description of the Related Art

A piezoresistive sensor includes a detection beam including a linear piezoresistor, a support beam, a weight portion, and a stationary portion. In some piezoresistive sensors, the support beam doubles as the detection beam. The detection beam, the support beam, the weight portion, and the stationary portion are formed by etching a semiconductor substrate. An example of the piezoresistive sensor is disclosed in Japanese Unexamined Patent Application Publication No. 2010-139263.

FIG. 9A is a schematic diagram illustrating an imaginary section of a detection beam 132 of the above piezoresistive sensor. In the piezoresistive sensor, the detection beam 132 detects angular acceleration about an axis perpendicular to a main surface of the piezoresistive sensor. The detection beam 132 includes a piezoresistor 132r and a base 132s. The piezoresistor 132r, which corresponds to a region formed in a manner in which donors or acceptors are diffused in a portion 132s₁ of a semiconductor substrate, has a polarity different from that of the portion 132s₁ of the semiconductor substrate. In FIG. 9A, the piezoresistor 132r extends in the direction perpendicular to the page.

During formation of the piezoresistor 132r, carriers in the portion 132s₁ of the original semiconductor substrate and carriers in the piezoresistor 132r are recombined. For this reason, it is considered that a depletion layer DL in which carriers are virtually absent is formed around the piezoresistor 132r. That is, the base 132s includes the portion 132s₁ of the remaining original semiconductor substrate and the depletion layer DL.

It has been known that, in the piezoresistive sensor, a stress that is applied to the piezoresistor 132r increases and detection sensitivity of angular acceleration improves in a manner in which the width of the detection beam 132 in the left and right direction in the figure is decreased. However, in the case where the width of the detection beam 132 in the above direction is decreased, as illustrated in FIG. 9B, the depletion layer DL formed around the piezoresistor 132r reaches both side surfaces of the detection beam 132.

As illustrated in FIG. 9A, in the case where the detection beam 132 is wide and the depletion layer DL does not reach both side surfaces of the detection beam 132, the detection beam 132 is electrically stable. For this reason, the effect of a noise from the outside is suppressed, and a ratio (referred to below as a signal to noise ratio) of a detection signal to the noise is high.

As illustrated in FIG. 9B, however, in the case where the depletion layer DL reaches both side surfaces of the detection beam 132, the inside of the detection beam 132 is electrically unstable. For this reason, there is a risk that the effect of a noise from the outside increases, and that the signal to noise ratio is low.

In the above description, the detection beam that detects angular acceleration is described. Similar concerns apply to a detection beam that detects acceleration, in the case where the detection beam is narrow and the depletion layer around the piezoresistor reaches one of the side surfaces of the detection beam.

### SUMMARY OF THE INVENTION

Preferred embodiments of the present invention provide piezoresistive sensors that enable the effect of a noise from the outside to be significantly reduced or prevented.

According to preferred embodiments of the present invention, in a piezoresistive sensor including a detection beam including a linear piezoresistor and a base in which the piezoresistor is embedded, the structure of the base is improved.

According to a preferred embodiment of the present invention, a piezoresistive sensor includes a detection beam including a linear piezoresistor made of an n-type semiconductor or a p-type semiconductor and a base in which the piezoresistor is embedded.

The piezoresistor is disposed on a first main surface side of the detection beam. The base includes a depletion layer, a first region, and at least one second region. The depletion layer surrounds the piezoresistor and is adjacent to the piezoresistor. The first region is made of a semiconductor having a polarity different from a polarity of the piezoresistor. The at least one second region is made of a semiconductor having a polarity different from the polarity of the piezoresistor and an impurity concentration higher than an impurity concentration of the first region. The at least one second region is exposed from one of side surfaces of the detection beam. The depletion layer is surrounded by a region defined by the first region and the at least one second region.

In the piezoresistive sensor, the at least one second region inhibits the depletion layer from being exposed from the corresponding side surface of the detection beam, and the detection beam is electrically stable. For this reason, the effect of a noise from the outside is significantly reduced or prevented, and the signal to noise ratio is high.

A piezoresistive sensor according to a preferred embodiment of the present invention preferably includes the following features. That is, preferably, the detection beam includes the piezoresistor, and the detection beam and the piezoresistor extend in the same or substantially the same direction. The at least one second region includes two second regions, one of which is exposed from the one of the side surfaces of the detection beam and the other of which is exposed from the other side surface of the detection beam.

In the piezoresistive sensor, the two second regions are provided, one of which is exposed from the one of the side surfaces of the detection beam and the other of which is exposed from the other side surface of the detection beam. Accordingly, the detection beam is electrically stable, because the second regions prevent the depletion layer from being exposed from the side surfaces of the detection beam, for example, even in the case where the width of the detection beam is decreased to increase the detection sensitivity of angular acceleration. For this reason, the effect of a noise from the outside is significantly reduced or prevented, and the signal to noise ratio is high.

In a piezoresistive sensor according to a preferred embodiment of the present invention, the effect of a noise from the outside is significantly reduced or prevented, and the signal to noise ratio is high.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a perspective view of a piezoresistive sensor according to a preferred embodiment of the present invention.

FIG. 2 is an enlarged plan view of a detection portion A of the piezoresistive sensor.

FIG. 3A is an enlarged plan view of a region C containing a first detection beam included in the detection portion A.

FIG. 3B is a circuit diagram illustrating connection between piezoresistors in detection beams of the detection portion A.

FIG. 4 is a schematic sectional view of the first detection beam taken along line A-A and denoted by arrows in FIG. 3A.

FIGS. 5A to 5D are schematic diagrams illustrating an example of a method of manufacturing the first detection beam according to a preferred embodiment of the present invention.

FIG. 6 is an enlarged plan view of a detection portion B of the piezoresistive sensor.

FIG. 7A is an enlarged plan view of a region D containing a fifth detection beam included in the detection portion B.

FIG. 7B is a circuit diagram illustrating connection between piezoresistors in the fifth detection beam.

FIG. 8 is a schematic sectional view of the fifth detection beam taken along line B-B and denoted by arrows in FIG. 7A.

FIGS. 9A and 9B are schematic diagrams illustrating an imaginary section of the detection beam of the piezoresistive sensor in the description of the related art.

### DETAILED DESCRIPTION OF THE PREFERRED EMBODIMENTS

Preferred embodiments of the present invention will hereinafter be described, and features of the present invention will be described in detail. Examples of piezoresistive sensors according to preferred embodiments of the present invention include a sensor used to control the position of a head of a hard disk drive and to stop writing when an impact is detected, but the piezoresistive sensor is not limited thereto.

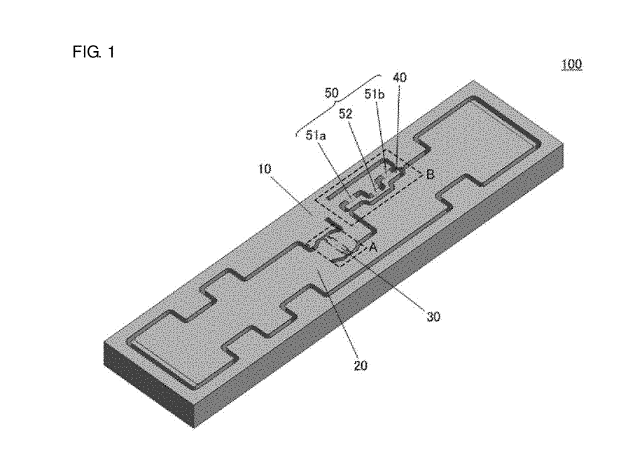

A piezoresistive sensor 100, which is the piezoresistive sensor according to a preferred embodiment of the present invention, will be described with reference to FIG. 1 to FIG. 8. The drawings are schematically illustrated, and the dimensions of an actual product are not necessarily reflected therein. In addition, variations in the shape of components that occur in manufacturing processes are not necessarily reflected to the drawings. That is, even if a difference from an actual product is shown in the drawings, it can be said that the drawings illustrate an actual product in essential aspects.

FIG. 1 is a perspective view of the piezoresistive sensor 100. The piezoresistive sensor 100 includes a stationary portion 10, a first weight portion 20, a first beam portion 30, a second weight portion 40, a second beam portion 50, and a control unit, not illustrated. These components are preferably formed by etching a semiconductor substrate, for example. The semiconductor substrate is preferably made of an n-type semiconductor and is a Si substrate in which donors, such as phosphorus (P) impurities, are diffused such that the concentration of the donors is uniform within an error range. The concentration of the donors is preferably less than about 1×10¹⁶ (atoms/cm³), for example. The concentration of the donors is determined in accordance with a drive voltage described later.

The stationary portion 10 preferably has a frame shape and surrounds a region including the first weight portion 20, the first beam portion 30, the second weight portion 40, and the second beam portion 50. The stationary portion 10 is secured to, for example, a housing, not illustrated. The shapes of the above components are not limited to the shape illustrated in FIG. 1.

The first weight portion 20 is elastically supported by the first beam portion 30 with respect to the stationary portion 10. The stationary portion 10, the first weight portion 20, the first beam portion 30, and the control unit, not illustrated, detect angular acceleration that occurs about an axis perpendicular or substantially perpendicular to a main surface of the piezoresistive sensor 100 when the piezoresistive sensor 100 rotates (detection portion A).

The second weight portion 40 is elastically supported by the second beam portion 50 with respect to the stationary portion 10. The stationary portion 10, the second weight portion 40, the second beam portion 50, and the control unit, not illustrated, detect acceleration that occurs in the axial direction parallel to the main surface of the piezoresistive sensor 100, for example, when the piezoresistive sensor 100 is impacted (detection portion B). The design of the second weight portion 40 illustrated in FIG. 1 may be changed in a manner in which the position of center of gravity is adjusted so that acceleration that occurs in the axial direction perpendicular or substantially perpendicular to the main surface of the piezoresistive sensor 100 is detected.

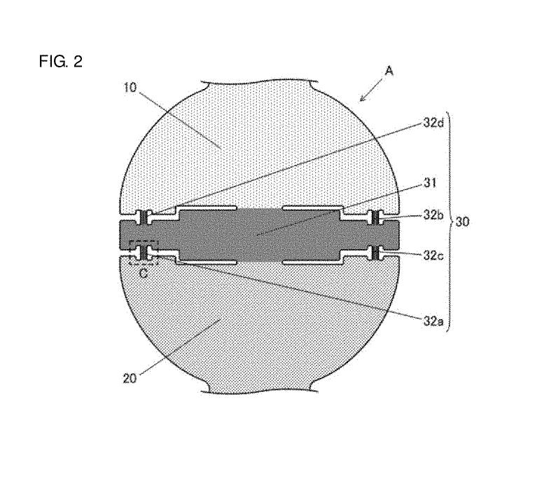

FIG. 2 is an enlarged view of the detection portion A that detects angular acceleration relating to rotation about the axis perpendicular or substantially perpendicular to the main surface of the piezoresistive sensor 100. The first beam portion 30 includes a first support beam 31, a first detection beam 32a, a second detection beam 32b, a third detection beam 32c, and a fourth detection beam 32d. The first support beam 31 is connected to the stationary portion 10 and the first weight portion 20. The second detection beam 32b and the fourth detection beam 32d are connected to the stationary portion 10 and the first support beam 31. The first detection beam 32a and the third detection beam 32c are connected to the first weight portion 20 and the first support beam 31.

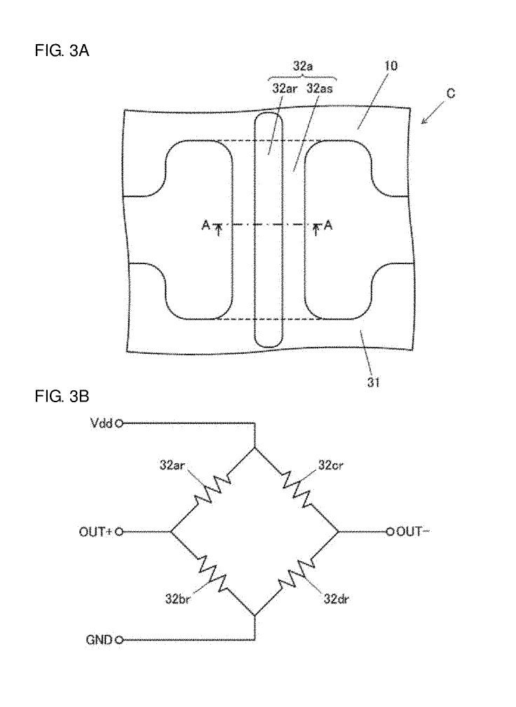

FIG. 3A is an enlarged plan view of a region C including the first detection beam 32a included in the detection portion A. The first detection beam 32a includes a linear first piezoresistor 32ar and a first base 32as in which the first piezoresistor 32ar is embedded. The first piezoresistor 32ar is disposed on a first main surface side of the first detection beam 32a, and the first detection beam 32a and the first piezoresistor 32ar extend in the same direction. The first piezoresistor 32ar is connected at an end thereof to a wiring portion, not illustrated, disposed near the stationary portion 10 and connected at the other end to a wiring portion, not illustrated, disposed in the first weight portion 20.

The first piezoresistor 32ar is preferably made of a p-type semiconductor and is a portion of a Si substrate in which acceptors, such as boron (B) impurities, are diffused such that the concentration of the acceptors peaks at a position deeper than a first main surface of the first detection beam 32a. The peak value of the concentration of the acceptors is preferably not less than about 1×10¹⁶ (atoms/cm³) and less than about 1×10¹⁸ (atoms/cm³), for example. Each wiring portion is preferably also made of a p-type semiconductor. The peak value of the concentration of acceptors, such as B, in each wiring portion is preferably about 1×10¹⁸ (atoms/cm³) or more, for example. The second detection beam 32b, the third detection beam 32c, and the fourth detection beam 32d preferably have the same or substantially the same structure. The above concentrations are determined in accordance with resistance values (power consumption) and temperature characteristics.

FIG. 3B is a circuit diagram illustrating the connection between piezoresistors in the first detection beam 32a, the second detection beam 32b, the third detection beam 32c, and the fourth detection beam 32d of the detection portion A. In the detection portion A, a voltage (for example, about 10 V) set on the basis of a ground terminal GND is applied to a power terminal V_{dd}. The rotation about the axis perpendicular or substantially perpendicular to the main surface of the piezoresistive sensor 100 causes each piezoresistor to be elastically deformed, and different voltages are outputted to a first output terminal OUT₊ and a second output terminal OUT₋. A difference in the voltage between the output terminals is calculated by the control unit, not illustrated, to obtain angular acceleration that occurs about the axis perpendicular or substantially perpendicular to the main surface of the piezoresistive sensor 100.

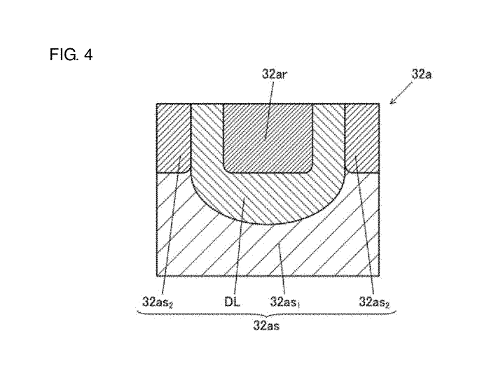

FIG. 4 is a schematic sectional view of the first detection beam 32a taken along line A-A and denoted by arrows in FIG. 3A. The first detection beam 32a includes the linear first piezoresistor 32ar and the first base 32as as described above. The first base 32as includes the depletion layer DL, a first region 32as₁, and two second regions 32as₂. The depletion layer DL surrounds the first piezoresistor 32ar and is adjacent to the first piezoresistor 32ar. The first piezoresistor 32ar has the concentration of the acceptors described above. Carriers (electrons or holes) are virtually absent in the depletion layer DL.

According to the present preferred embodiment, the first region 32as₁ is preferably made of an n-type semiconductor having an impurity concentration lower than the impurity concentration of the first piezoresistor 32ar, which is the same material as the above semiconductor substrate. The phrase “having an impurity concentration lower than the impurity concentration of the first piezoresistor 32ar” means that a uniform concentration of the donors in the first region 32as₁ is lower than a peak value of the concentration of the acceptors in the first piezoresistor 32ar. The impurity concentration of the first region 32as₁ may be higher than the impurity concentration of the first piezoresistor 32ar.

Each second region 32as₂ is preferably made of an n-type semiconductor having an impurity concentration higher than the impurity concentration of the first region 32as₁. The phrase “having an impurity concentration higher than the impurity concentration of the first region 32as₁ means that a peak value of the concentration of the donors in each second region 32as₂ is higher than a peak value of the concentration of the donors in the first region 32as₁. The peak value of the concentration of the donors in each second region 32as₂ is preferably about 1×10¹⁸ (atoms/cm³) or more, for example.

The second regions 32as₂ are adjacent to the depletion layer DL and the first region 32as₁. That is, the depletion layer DL is surrounded by a region defined by the first region 32as₁ and the second regions 32as₂. In this case, as illustrated in FIG. 4, it is preferable that the depletion layer DL be exposed neither from the side surfaces of the first detection beam 32a nor from a second main surface of the first detection beam 32a. One of the two second regions 32as₂ is exposed from one of the side surfaces parallel or substantially parallel to the direction in which the first detection beam 32a extends, and the other second region 32as₂ is exposed from the other side surface parallel or substantially parallel to the direction in which the first detection beam 32a extends. The second detection beam 32b, the third detection beam 32c, and the fourth detection beam 32d preferable have the same or substantially the same structure.

In each detection beam, there are two second regions, one of which is exposed from one of the side surfaces of the detection beam and the other of which is exposed from the other side surface of the detection beam. Accordingly, each detection beam is electrically stable, because the second regions prevent the depletion layer from being exposed from the side surfaces of the detection beam, for example, even in the case where the width of the detection beam is decreased to increase the detection sensitivity of angular acceleration. For this reason, the effect of a noise from the outside is significantly reduced or prevented, and the signal to noise ratio is high.

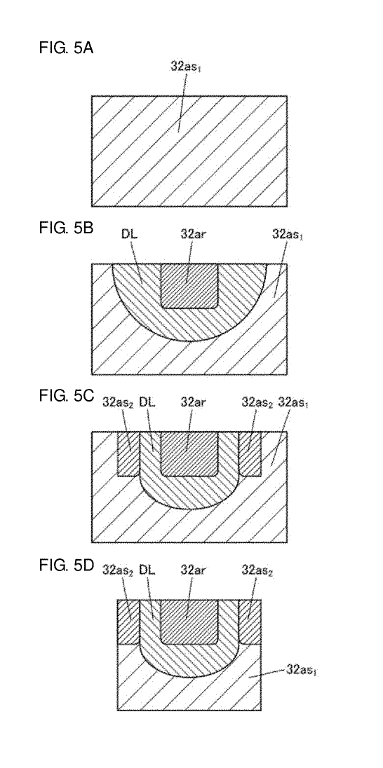

FIGS. 5A to 5D are schematic diagrams illustrating an example of a method of manufacturing the first detection beam 32a according to a preferred embodiment of the present invention. FIGS. 5A to 5D correspond to the schematic sectional view of the first detection beam 32a taken along line A-A and denoted by the arrows in FIG. 3A. An illustration and description of the shape of each wiring portion to which the first piezoresistor 32ar is connected are omitted.

FIG. 5A schematically illustrates a process of fabricating or preparing an n-type semiconductor substrate (first region 32as₁) in a manner in which donors, such as P, are diffused in a Si substrate such that the concentration of the donors is preferably less than about 1×10¹⁶ (atoms/cm³), for example. At this time, the semiconductor substrate is wider than the first detection beam 32a. The concentration of the donors in the semiconductor substrate is uniform within an error range. A shield layer may preferably be formed on a surface of the semiconductor substrate such that the concentration of donors, such as P, is no less than about 1×10¹⁶ (atoms/cm³) and less than about 1×10¹⁸ (atoms/cm³), for example.

FIG. 5B schematically illustrates a process of diffusing acceptors, such as B, in the Si substrate, that is, the semiconductor substrate (first region 32as₁) such that the concentration of the acceptors peaks at a position deeper than the first main surface of the first detection beam 32a. The peak value of the concentration of the acceptors is preferably no less than about 1×10¹⁶ (atoms/cm³) and less than about 1×10¹⁸ (atoms/cm³), for example. In this process, the first piezoresistor 32ar is formed. At this time, carriers (electrons) in the semiconductor substrate and carriers (holes) in the first piezoresistor 32ar are recombined, and the depletion layer DL, in which carriers are virtually absent, is formed around the first piezoresistor 32ar at the same time.

FIG. 5C schematically illustrates a process of diffusing donors, such as P, in the Si substrate, that is, the semiconductor substrate containing the depletion layer DL such that the concentration of the donors peaks at a position deeper than the first main surface of the first detection beam 32a. The peak value of the concentration of the donors is preferably about 1×10¹⁸ (atoms/cm³) or more, for example. In this process, the two second regions 32as₂ are formed. The remaining original semiconductor substrate corresponds to the first region 32as₁. That is, the depletion layer DL is surrounded by a region defined by the first region 32as₁ and the second regions 32as₂. At this time, however, the second regions 32as₂ are not exposed.

FIG. 5D schematically illustrates a process of processing the semiconductor substrate by, for example, dry etching to adjust the width of the first detection beam 32a to the required width. In this process, one of the two second regions 32as₂ is exposed from one of the side surfaces of the first detection beam 32a, and the other second region 32as₂ is exposed from the other side surface of the first detection beam 32a. Through the above processes, the first detection beam 32a is formed. The second detection beam 32b, the third detection beam 32c, and the fourth detection beam 32d are formed through the same or substantially the same processes.

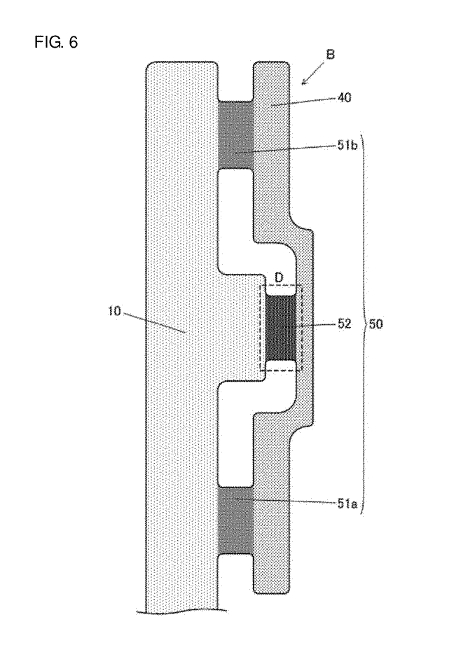

FIG. 6 is an enlarged view of the detection portion B that detects acceleration that occurs in the axial direction parallel or substantially parallel to the main surface of the piezoresistive sensor 100. The second beam portion 50 includes a second support beam 51a, a third support beam 51b, and a fifth detection beam 52. The second support beam 51a, the third support beam 51b, and the fifth detection beam 52 are connected to the stationary portion 10 and the second weight portion 40.

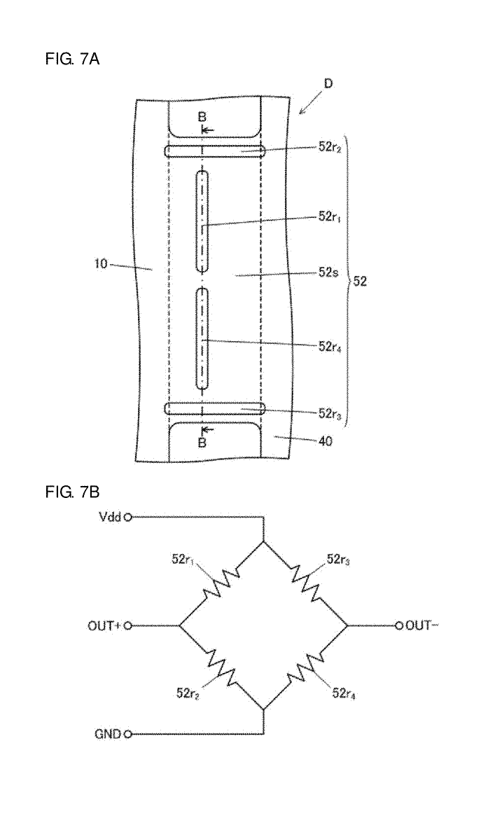

FIG. 7A is an enlarged plan view of a region D containing the fifth detection beam 52 included in the detection portion B. The fifth detection beam 52 includes a fifth piezoresistor 52r₁, a sixth piezoresistor 52r₂, a seventh piezoresistor 52r₃, and an eighth piezoresistor 52r₄ that are linear, and a second base 52s in which the piezoresistors are embedded. The piezoresistors are provided on a first main surface side of the fifth detection beam 52.

In the fifth detection beam 52, the fifth piezoresistor 52r₁ and the eighth piezoresistor 52r₄ extend in the direction perpendicular or substantially perpendicular to the direction in which the fifth detection beam 52 extends. The sixth piezoresistor 52r₂ and the seventh piezoresistor 52r₃ extend in the same or substantially the same direction as the fifth detection beam 52 extends. The piezoresistors are connected to respective wiring portions, not illustrated.

The fifth piezoresistor 52r₁, the sixth piezoresistor 52r₂, the seventh piezoresistor 52r₃, and the eighth piezoresistor 52r₄ are each preferably made of a p-type semiconductor and have the same or substantially the same concentration of the acceptors as the first piezoresistor 32ar described above. Each wiring portion, not illustrated, is preferably also made of a p-type semiconductor and has the same or substantially the same concentration of the acceptors as described above.

FIG. 7B is a circuit diagram illustrating the connection between piezoresistors in the detection portion B. In the detection portion B, a voltage (for example, about 10 V) set on the basis of the ground terminal GND is applied to a power terminal V_{dd} as in the detection portion A. An impact in the axial direction parallel or substantially parallel to the main surface of the piezoresistive sensor 100 causes each piezoresistor to be elastically deformed, and different voltages are outputted to a first output terminal OUT₊ and a second output terminal OUT₋. A difference in the voltage between the output terminals is calculated by the control unit, not illustrated, to obtain acceleration that occurs in the axial direction parallel or substantially parallel to the main surface of the piezoresistive sensor 100.

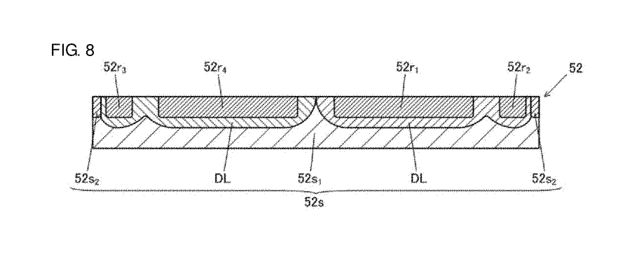

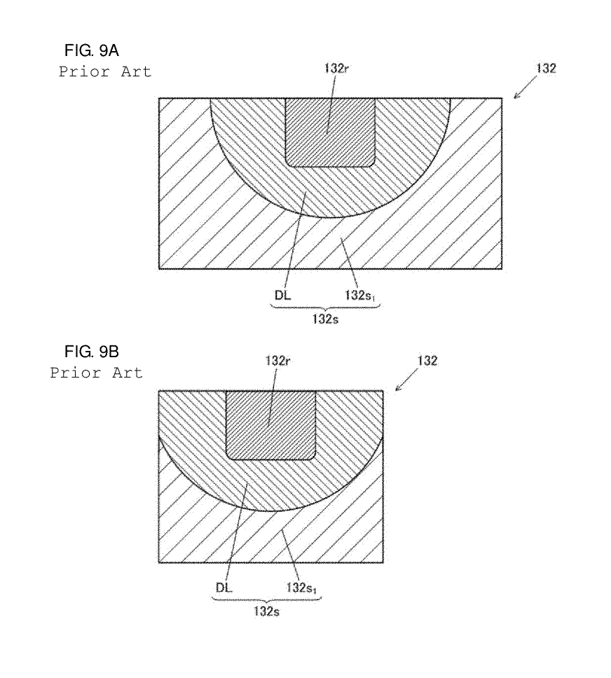

FIG. 8 is a schematic sectional view of the fifth detection beam 52 taken along line B-B and denoted by arrows in FIG. 7A. The fifth detection beam 52 includes the fifth piezoresistor 52r₁ the sixth piezoresistor 52r₂, the seventh piezoresistor 52r₃, and the eighth piezoresistor 52r₄ that are linear, and the second base 52s as described above. The second base 52s includes the depletion layers DL, the first region 52s₁, and the two second regions 52s₂.

The first region 52s₁ is preferably made of the same semiconductor as the first region 32as₁ in the region C. Each second region 52s² is preferably made of the same semiconductor as the second regions 32as₂ in the region C. The positional relationship between the first region 52s₁, the second regions 52s₂, and the depletion layers DL is the same as the region C. That is, the depletion layers DL are surrounded by a region defined by the first region 52s₁ and the second regions 52s₂. At this time, as illustrated in FIG. 8, it is preferable that the depletion layers DL be exposed neither from the side surfaces of the fifth detection beam 52 nor from a second main surface of the fifth detection beam 52.

One of the two second regions 52s₂ is exposed from one of the side surfaces of the fifth detection beam 52, and the other second region 52s₂ is exposed from the other side surface of the fifth detection beam 52. That is, in the fifth detection beam 52, one of the two second regions 52s₂ is exposed from one of the side surfaces of the detection beam, and the other second region 52s₂ is exposed from the other side surface of the detection beam. Accordingly, the second regions 52s₂ prevent the depletion layers DL from being exposed from the side surfaces of the fifth detection beam 52, and the fifth detection beam 52 is electrically stable. For this reason, the effect of a noise from the outside is significantly reduced or prevented, and the signal to noise ratio is high.

Preferred embodiments are described by way of example herein. The present invention is not limited to the preferred embodiments. Various applications and modifications may be made within the scope of the present invention. For example, each piezoresistor may be made of an n-type semiconductor, and the first region, the second region, and the shield layer provided as necessary may each be made of a p-type semiconductor.

The piezoresistive sensors according to preferred embodiments of the present invention may preferably include an excitation portion (continuous resonance vibration portion). In this case, angular speed based on the Coriolis force resulted from rotation is able to be detected.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A piezoresistive sensor, comprising:
a detection beam including a linear piezoresistor made of an n-type semiconductor or a p-type semiconductor and a base in which the piezoresistor is embedded; wherein
the piezoresistor is disposed on a first main surface side of the detection beam;
the base includes a depletion layer that surrounds the piezoresistor and that is adjacent to the piezoresistor, a first region made of a semiconductor having a polarity different from a polarity of the piezoresistor, and at least one second region made of a semiconductor having a polarity different from the polarity of the piezoresistor and an impurity concentration higher than an impurity concentration of the first region;
the at least one second region is exposed from one of side surfaces of the detection beam; and
the depletion layer is surrounded by a region defined by the first region and the at least one second region.

2. The piezoresistive sensor according to claim 1, wherein
the detection beam includes the piezoresistor, and the detection beam and the piezoresistor extend in a same direction or substantially a same direction; and
the at least second region includes two second regions, one of the two second regions is exposed from the one of the side surfaces of the detection beam and another of the two second regions is exposed from the other of the side surfaces of the detection beam.

3. The piezoresistive sensor according to claim 1, wherein the piezoresistor is made of a p-type semiconductor and a portion of a Si substrate in which acceptors are diffused such that a concentration of the acceptors peaks at a position deeper than a first main surface of the detection beam.

4. The piezoresistive sensor according to claim 3, wherein the acceptors are boron impurities.

5. The piezoresistive sensor according to claim 3, wherein a peak value of the concentration of the acceptors is not less than about 1×10¹⁶ (atoms/cm³) and less than about 1×10¹⁸ (atoms/cm³).

6. The piezoresistive sensor according to claim 1, wherein the first region is made of an n-type semiconductor having an impurity concentration lower than an impurity concentration of the piezoresistor.

7. The piezoresistive sensor according to claim 1, wherein each of the at least one second region is made of an n-type semiconductor.

8. The piezoresistive sensor according to claim 7, wherein a peak value of a concentration of donors in each of the at least one second region is about 1×10¹⁸ (atoms/cm³) or more.

9. The piezoresistive sensor according to claim 1, wherein the depletion layer is not exposed from either of the side surfaces of the detection beam or from a second main surface of the detection beam.

10. A piezoresistive sensor, comprising:
a plurality of detection beams, each including a linear piezoresistor made of an n-type semiconductor or a p-type semiconductor and a base in which the piezoresistor is embedded;
wherein in each of the plurality of detection beams:
the piezoresistor is disposed on a first main surface side of the detection beam;
the base includes a depletion layer that surrounds the piezoresistor and that is adjacent to the piezoresistor, a first region made of a semiconductor having a polarity different from a polarity of the piezoresistor, and at least one second region made of a semiconductor having a polarity different from the polarity of the piezoresistor and an impurity concentration higher than an impurity concentration of the first region;
the at least one second region is exposed from one of side surfaces of the detection beam; and
the depletion layer is surrounded by a region defined by the first region and the at least one second region.

11. The piezoresistive sensor according to claim 10, wherein
in each of the plurality of detection beams:
the detection beam and the piezoresistor extend in a same direction; and
the at least second region includes two second regions, one of the two second regions which is exposed from the one of the side surfaces of the detection beam and another of the two second regions is exposed from the other side surface of the detection beam.

12. The piezoresistive sensor according to claim 10, wherein, in each of the plurality of detection beams, the piezoresistor is made of a p-type semiconductor and a portion of a Si substrate in which acceptors are diffused such that a concentration of the acceptors peaks at a position deeper than a first main surface of the detection beam.

13. The piezoresistive sensor according to claim 12, wherein, in each of the plurality of detection beams the acceptors are boron impurities.

14. The piezoresistive sensor according to claim 12, wherein, in each of the plurality of detection beams, a peak value of the concentration of the acceptors is not less than about 1×10¹⁶ (atoms/cm³) and less than about 1×10¹⁸ (atoms/cm³).

15. The piezoresistive sensor according to claim 10 wherein, in each of the plurality of detection beams, the first region is made of an n-type semiconductor having an impurity concentration lower than an impurity concentration of the piezoresistor.

16. The piezoresistive sensor according to claim 10, wherein, in each of the plurality of detection beams, each of the at least one second region is made of an n-type semiconductor.

17. The piezoresistive sensor according to claim 16, wherein, in each of the plurality of detection beams, a peak value of a concentration of donors in each of the at least one second region is about 1×10¹⁸ (atoms/cm³) or more.

18. The piezoresistive sensor according to claim 16, wherein, in each of the plurality of detection beams, the depletion layer is not exposed from either of the side surfaces of the detection beam or from a second main surface of the detection beam.
